(19) United States
(12) Patent Application Publication
(10) Pub. No.: US 2024/0243057 A1
(43) Pub. Date: Jul. 18, 2024

(54) INTEGRATED CIRCUIT AND MANUFACTURING METHOD THEREOF

(71) Applicant: UNITED MICROELECTRONICS CORP., Hsin-Chu City (TW)

(72) Inventors: Da-Jun Lin, Kaohsiung City (TW); Bin-Siang Tsai, Changhua County (TW); Fu-Yu Tsai, Tainan City (TW)

(73) Assignee: UNITED MICROELECTRONICS CORP., Hsin-Chu City (TW)

(21) Appl. No.: 18/124,591

(22) Filed: Mar. 22, 2023

(30) Foreign Application Priority Data
Jan. 18, 2023 (TW) 112102158

(51) Int. Cl. H01L 23/522; H01L 21/768; H01L 23/00; H01L 27/08

(52) U.S. Cl. CPC H01L 23/5223; H01L 21/76805; H01L 23/5226; H01L 24/05; H01L 24/11; H01L 27/0805; H01L 2224/05026; H01L 2224/116; H01L 2924/19041; H01L 2924/30105

(57) ABSTRACT

An integrated circuit includes a substrate, an interconnection layer, an insulation layer, a metal bump structure, and a metal-insulator-metal capacitor. The interconnection layer is disposed above the substrate. The interconnection layer includes an interlayer dielectric layer and an interconnection structure disposed in the interlayer dielectric layer. The insulation layer is disposed on the interconnection layer, the metal bump structure is disposed on the insulation layer, and the metal-insulator-metal capacitor is disposed conformally on the metal bump structure and the insulation layer. A manufacturing method of the integrated circuit includes the following steps.

The interconnection layer is formed above the substrate. The insulation layer is formed on the interconnection layer, the metal bump structure is formed on the insulation layer, and the metal-insulator-metal capacitor is formed conformally on the metal bump structure and the insulation layer.

### BACKGROUND OF THE INVENTION

### 1. Field of the Invention

The present invention relates to an integrated circuit and a manufacturing method thereof, and more particularly, to an integrated circuit including a metal-insulator-metal capacitor and a manufacturing method thereof.

### 2. Description of the Prior Art

In modern society, the micro-processor systems composed of integrated circuits (ICs) are applied popularly in our living. Many electrical products, such as personal computers, mobile phones, and home appliances, include ICs. With the development of technology and the increasingly imaginative applications of electrical products, the design of ICs tends to be smaller, more delicate and more diversified.

In the recent electrical products, IC devices, such as metal oxide semiconductor (MOS) transistors, capacitors, or resistors, are produced from silicon based substrates that are fabricated by semiconductor manufacturing processes. A complicated IC system may be composed of the IC devices electrically connected with one another. Generally, a capacitor structure may be composed of a top electrode, a dielectric layer, and a bottom electrode. The capacitor structure is traditionally disposed in an inter-metal dielectric (IMD) layer on a silicon based substrate and includes a metal-insulator-metal (MIM) capacitor structure. However, as the function and performance demands of electronic products continue to increase, the complexity and integration of integrated circuits have also increased relatively. As a result, the space where the capacitor structure can be formed is gradually reduced, which also limits the capacitance of the capacitor structure and causes difficulties in the design of integrated circuits.

### SUMMARY OF THE INVENTION

An integrated circuit and a manufacturing method thereof are provided in the present invention. A metal-insulator-metal (MIM) capacitor is formed conformally on a metal bump structure and an insulation layer for increasing the capacitance of the capacitor and/or utilizing the space above an interconnection structure to form a relatively large capacitor structure.

According to an embodiment of the present invention, an integrated circuit is provided. The integrated circuit includes a substrate, an interconnection layer, an insulation layer, a metal bump structure, and a metal-insulator-metal (MIM) capacitor. The interconnection layer is disposed above the substrate, and the interconnection layer includes an interlayer dielectric layer and an interconnection structure disposed in the interlayer dielectric layer. The insulation layer is disposed on the interconnection layer, the metal bump structure is disposed on the insulation layer, and the MIM capacitor is disposed conformally on the metal bump structure and the insulation layer.

According to an embodiment of the present invention, a manufacturing method of an integrated circuit is provided. The method includes the following steps. An interconnection layer is formed above a substrate. The interconnection layer includes an interlayer dielectric layer and an interconnection structure disposed in the interlayer dielectric layer. An insulation layer is formed on the interconnection layer, a metal bump structure is formed on the insulation layer, and a metal-insulator-metal (MIM) capacitor is formed conformally on the metal bump structure and the insulation layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional schematic drawing illustrating an integrated circuit according to a first embodiment of the present invention.

FIG. 2 is a schematic drawing illustrating an integrated circuit according to an embodiment of the present invention.

FIG. 3 is a schematic drawing illustrating an integrated circuit according to another embodiment of the present invention.

FIGS. 4-12 are schematic drawings illustrating a manufacturing method of an integrated circuit according to the first embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, and FIG. 12 is a schematic drawing in a step subsequent to FIG. 11.

FIG. 13 is a cross-sectional schematic drawing illustrating an integrated circuit according to a second embodiment of the present invention.

FIG. 14 is a cross-sectional schematic drawing illustrating an integrated circuit according to a third embodiment of the present invention.

FIG. 15 is a cross-sectional schematic drawing illustrating an integrated circuit according to a fourth embodiment of the present invention.

FIG. 16 is a cross-sectional schematic drawing illustrating an integrated circuit according to a fifth embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

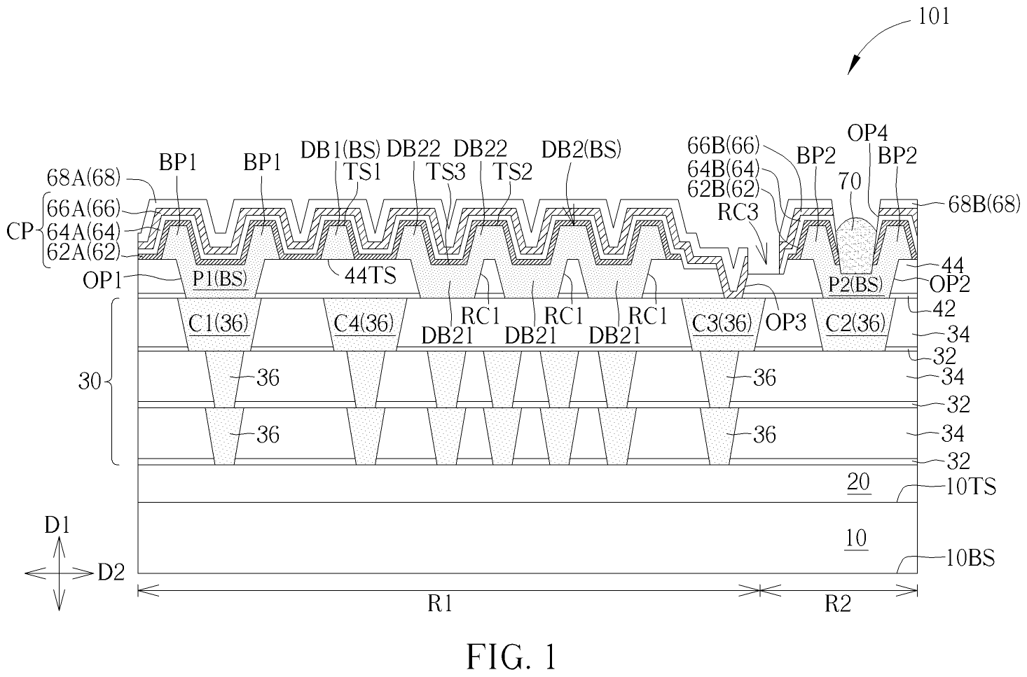

Please refer to FIG. 1. FIG. 1 is a cross-sectional schematic drawing illustrating an integrated circuit 101 according to a first embodiment of the present invention. As shown in FIG. 1, the integrated circuit 101 includes a substrate 10, an interconnection layer 30, an insulation layer 44, a metal bump structure BS, and a metal-insulator-metal (MIM) capacitor CP. The interconnection layer 30 is disposed above the substrate 10, and the interconnection layer 30 includes an interlayer dielectric layer 34 and an interconnection structure 36 disposed in the interlayer dielectric layer 34. The insulation layer 44 is disposed on the interconnection layer 30, the metal bump structure BS is disposed on the insulation layer 44, and the MIM capacitor CP is disposed conformally on the metal bump structure BS and the insulation layer 44. As the MIM capacitor CP is formed conformally on the metal bump structure BS and the insulation layer 44, the surface area of the MIM capacitor CP may be increased by the surface undulations of the metal bump structure BS, and the capacitance of the MIM capacitor CP may be increased accordingly. In addition, the MIM capacitor CP is formed in the space above the interconnection layer 30 instead of forming the capacitor of the present invention in the interconnection layer 30, the influence of the interconnection structure 36 and related limitations may be improved, and the relatively large capacitor structure may be formed to meet the needs of related products accordingly.

In some embodiments, the substrate 10 may include a semiconductor substrate, such as a silicon substrate, a silicon germanium semiconductor substrate, a silicon-on-insulator (SOI) substrate, or a substrate made of other suitable materials. In addition, the integrated circuit 101 may further include a device layer 20 disposed between the substrate 10 and the interconnection layer 30. The device layer 20 may include active elements (such as transistors, diodes, and so forth), passive elements (such as capacitors, resistors, and so forth), and/or other related circuits, and the interconnection structure 36 in the interconnection layer 30 maybe electrically connected to the elements and/or the circuits in the device layer 20, but not limited thereto. In some embodiments, the device layer 20 maybe formed by the front end of line (FEOL) process in the semiconductor manufacturing process, the interconnection layer 30 maybe formed by the back end of line (BEOL) process in the semiconductor manufacturing process, and the MIM capacitor CP may be regarded as being formed by a process performed after the interconnection layer 30 is formed (such as a far back end of line (FBEOL) process). Additionally, in some embodiments, the interconnection layer 30 may include a plurality of interlayer dielectric layers 34 and a plurality of etching stop layers 32 alternately disposed in a vertical direction D1, and the interconnection structure 36 may include a plurality of via conductor structures and a plurality of trench conductor structures alternately disposed in the vertical direction D1 and penetrating through the corresponding interlayer dielectric layers 34 and the corresponding etching stop layers, respectively. The etching stop layer 32 may include silicon oxide, silicon nitride, silicon carbonitride, or other suitable dielectric materials, and the interlayer dielectric layer 34 may include a low dielectric constant (low-k) dielectric material or other suitable dielectric materials. The interconnection structure 36 (such as the via conductor structure and/or the trench conductor structure described above) may include a barrier layer and a low electrical resistance material disposed on the barrier layer, but not limited thereto. The above-mentioned low electrical resistance material may include a material with a relatively low electrical resistivity, such as copper, aluminum, tungsten, and so forth, and the above-mentioned barrier layer may include titanium nitride, tantalum nitride, or other suitable electrically conductive barrier materials.

In some embodiments, the vertical direction D1 described above may be regarded as a thickness direction of the substrate 10. The substrate 10 may have a top surface 10TS and a bottom surface 10BS opposite to the top surface 10TS in the vertical direction D1. The interconnection layer 30, the insulation layer 44, the metal bump structure BS, and the MIM capacitor CP described above may be disposed at a side adjacent to the top surface 10TS. Horizontal directions substantially orthogonal to the vertical direction D1 (such as a horizontal direction D2 and other directions orthogonal to the vertical direction D1) may be substantially parallel with the top surface 10TS and/or the bottom surface 10BS of the substrate 10, but not limited thereto. In this description, a distance between the bottom surface 10BS of the substrate 10 and a relatively higher location and/or a relatively higher part in the vertical direction D1 is greater than a distance between the bottom surface 10BS of the substrate 10 and a relatively lower location and/or a relatively lower part in the vertical direction D1. The bottom or a lower portion of each component may be closer to the bottom surface 10BS of the substrate 10 in the vertical direction D1 than the top or upper portion of this component. Another component disposed above a specific component may be regarded as being relatively far from the bottom surface 10BS of the substrate 10 in the vertical direction D1, and another component disposed under a specific component may be regarded as being relatively close to the bottom surface 10BS of the substrate 10 in the vertical direction D1. Additionally, in this description, the top surface of a specific component may include the topmost surface of this component in the vertical direction D1, and the bottom surface of a specific component may include the bottommost surface of this component in the vertical direction D1, but not limited thereto.

In some embodiments, the MIM capacitor CP may include a bottom plate 62A, a capacitor dielectric layer 64A, and a top plate 66A. The bottom plate 62A may be disposed conformally on the metal bump structure BS and the insulation layer 44, at least a portion of the capacitor dielectric layer 64A may be disposed conformally on the bottom plate 62A, and at least a portion of the top plate 66A may be disposed conformally on the capacitor dielectric layer 64A. The bottom plate 62A and the top plate 66A may respectively include a single layer or multiple layers of electrically conductive materials, such as titanium, tantalum, aluminum, titanium nitride, tantalum nitride, copper, cobalt, or other suitable electrically conductive metallic materials, and the capacitor dielectric layer 64A may include a single layer or multiple layers of dielectric materials, such as silicon nitride, silicon-rich silicon nitride, silicon oxide, silicon oxynitride, a high dielectric constant (high-k) dielectric material (such as zirconium oxide, hafnium oxide, tantalum oxide, titanium oxide, or aluminum oxide), or other suitable dielectric materials. Additionally, in some embodiments, the integrated circuit 101 may further include an etching stop layer 42 disposed between the insulation layer 44 and the interconnection layer 30. The etching stop layer 42 may include silicon oxide, silicon nitride, silicon carbonitride, or other suitable dielectric materials, and the insulation layer 44 may include an insulation material different from the material of the etching stop layer 42. In some embodiments, the metal bump structure BS may include a first bump DB1, a second bump DB2, and a first connection pad P1. The bottom plate 62A of the MIM capacitor CP may be disposed conformally on the top surfaces of the first bump DB1, the second bump DB2, the first connection pad P1, and the insulation layer 44, and the bottom plate 62A may be directly connected with the first bump DB1, the second bump DB2, and the first connection pad P1. The first bump DB1 may protrude upwards from a top surface 44TS of the insulation layer 44 in the vertical direction D1, and the second bump DB2 may be partly disposed above the top surface 44TS of the insulation layer 44 and partly disposed in a recess RC1 penetrating through the insulation layer 44 and the etching stop layer 42 in the vertical direction D1 for increasing the surface step height of the second bump DB2. In some embodiments, the first bump DB1 and the second bump DB2 may be regarded as dummy bumps without being directly connected with the interconnection structure 36, and the first bump DB1 may not be directly connected with the second bump DB2 also. In some embodiments, a distance between a top surface TS1 of the first bump DB1 and the top surface 44TS of the insulation layer 44 in the vertical direction D1 may range from 5000 angstroms to 30000 angstroms for increasing the surface area and the capacitance of the MIM capacitor CP and avoiding excessive surface step difference which may affect the progress of subsequent related processes.

In some embodiments, the second bump DB2 may include a first portion DB21 and a second portion DB22. The first portion DB21 may be disposed in the recess RC1, the second portion DB22 may be disposed on the insulation layer 44 in the vertical direction D1, and the second portion DB22 may be directly connected with the first portion DB21. A top surface TS2 of the second portion DB22 may be higher than the top surface 44TS of the insulation layer 44 in the vertical direction D1, a top surface TS3 of the first portion DB21 may be lower than the top surface 44TS of the insulation layer 44 in the vertical direction D1, and a distance between the top surface TS2 of the second portion DB22 and the top surface 44TS of the insulation layer 44 in the vertical direction D1 may be substantially equal to the distance between the top surface TS1 of the first bump DB1 and the top surface 44TS of the insulation layer 44 in the vertical direction D1. Therefore, a distance between the top surface TS2 of the second portion DB22 and the top surface TS3 of the first portion DB21 in the vertical direction D1 may be greater than the distance between the top surface TS1 of the first bump DB1 and the top surface 44TS of the insulation layer 44 in the vertical direction D1. In other words, the surface step height of the second bump DB2 may be greater than the surface step height between the first bump DB1 and the insulation layer 44 for further increase the surface area and the capacitance of the MIM capacitor CP.

In some embodiments, a part of the first connection pad P1 may be disposed in an opening OP1 penetrating through the insulation layer 44 and the etching stop layer 42 in the vertical direction D1 for being electrically connected with a top connection portion C1 of the interconnection structure 36. In addition, the bottom plate 62A of the MIM capacitor CP may be disposed on and contacting the first connection pad P1 for being electrically connected with the first connection pad P1, and the bottom plate 62A may be electrically connected with the top connection portion C1 of the interconnection structure 36 via the first connection pad P1 accordingly. In some embodiments, the top connection portion (such as the top connection portion C1 or other top connection portions in the interconnection structure 36 located at the same level as the top connection portion C1) may be regarded as the topmost structure within the interconnection structure 36 in the vertical direction D1, and the top connection structure may be a trench conductor structure, but not limited thereto. In addition, another part of the first connection pad P1 may be disposed above the insulation layer 44 in the vertical direction D1 and may be regarded as a protruding portion BP1 protruding upwards from the top surface 44TS of the insulation layer 44 in the vertical direction D1, and a distance between a top surface of the protruding portion BP1 and the top surface 44TS of the insulation layer 44 in the vertical direction D1 may be substantially equal to the distance between the top surface TS1 of the first bump DB1 and the top surface 44TS of the insulation layer 44 in the vertical direction D1, but not limited thereto. The first bump DB1, the second bump DB2, and the first connection pad P1 may be regarded as different portions of the metal bump structure BS and have the same material composition, and the first bump DB1, the second bump DB2, and the first connection pad P1 may not be directly connected with one another, but not limited thereto.

In some embodiments, the metal bump structure BS may further include a second connection pad P2. A part of the second connection pad P2 may be disposed in an opening OP2 penetrating through the insulation layer 44 and the etching stop layer 42 in the vertical direction D1, and the second connection pad P2 may contact a top connection portion of the interconnection structure 36 (such as a top connection portion C2) for being electrically connected with the top connection portion by passing through the opening OP2. In some embodiments, the second connection pad P2 may be regarded as an input/output (I/O) pad, but not limited thereto. In addition, another part of the second connection pad P2 may be disposed above the insulation layer 44 in the vertical direction D1 and may be regarded as a protruding portion BP2 protruding upwards from the top surface 44TS of the insulation layer 44 in the vertical direction D1, and a distance between a top surface of the protruding portion BP2 and the top surface 44TS of the insulation layer 44 in the vertical direction D1 may be substantially equal to the distance between the top surface TS1 of the first bump DB1 and the top surface 44TS of the insulation layer 44 in the vertical direction D1, but not limited thereto. In some embodiments, a material composition of the second connection pad P2 may be identical to that of the first bump DB1, the second bump DB2, and the first connection pad P1, and the second connection pad P2 may be separated from the first bump DB1, the second bump DB2, and the first connection pad P1. In some embodiments, the MIM capacitor CP may be electrically separated from the second connection pad P2, and a part of the top plate 66A may be disposed in an opening OP3 penetrating through the insulation layer 44 and the etching stop layer 42 in the vertical direction D1 for being electrically connected with a top connection portion of the interconnection structure 36 (such as a top connection portion C3). In some embodiments, the top connection portion C1, the top connection portion C2, the top connection portion C3, and another top connection portion C4 may be electrically separated from one another, and a part of the metal bump structure BS and a part of the MIM capacitor CP may be located above the top connection portion C4 in the vertical direction D1. In other words, the first bump DB1 in the metal bump structure BS is preferably disposed above the top connection portion which has to be electrically separated from the MIM capacitor CP (such as the top connection portion C4) for avoiding electrically connecting the bottom plate 62A with the top connection portion which has to be electrically separated from the MIM capacitor CP via the second bump DB2.

In some embodiments, the integrated circuit 101 may further include an electrically conductive pattern 62B, a dielectric pattern 64B, an electrically conductive pattern 66B, a passivation layer 68, and a connection material 70. The electrically conductive pattern 62B may be disposed conformally on the second connection pad P2 and the insulation layer 44, the dielectric pattern 64B may be disposed conformally on the electrically conductive pattern 62B, and the electrically conductive pattern 66B may be disposed conformally on the dielectric pattern 64B. In some embodiments, the material compositions of the electrically conductive pattern 62B, the dielectric pattern 64B, and the electrically conductive pattern 66B may be identical to those of the bottom plate 62A, the capacitor dielectric layer 64A, and the top plate 66A, respectively, and the electrically conductive pattern 62B, the dielectric pattern 64B, and the electrically conductive pattern 66B may be separated from the MIM capacitor CP, but not limited thereto. A first portion 68A of the passivation layer 68 maybe disposed on the top plate 66A and disposed corresponding to the top plate 66A in the vertical direction D1 completely, and a second portion 68B of the passivation layer 68 maybe disposed on the electrically conductive pattern 66B and disposed corresponding to the electrically conductive pattern 66B in the vertical direction D1 completely, but not limited thereto. The passivation layer 68 may include oxide, nitride (such as silicon nitride), or other suitable materials with passivation effects. The connection material 70 maybe disposed on the second connection pad P2 for electrically connecting an outer circuit with the second connection pad P2 via the connection material 70. In some embodiments, the substrate 10 may have at least one first region R1 and at least one second region R2, the MIM capacitor CP and the first bump DB1, the second bump DB2, and the first connection pad P1 in the metal bump structure BS may be disposed above the first region R1 in the vertical direction D1, and the electrically conductive pattern 62B, the dielectric pattern 64B, the electrically conductive pattern 66B, and the second connection pad P2 in the metal bump structure BS may be disposed above the second region R2 in the vertical direction D1.

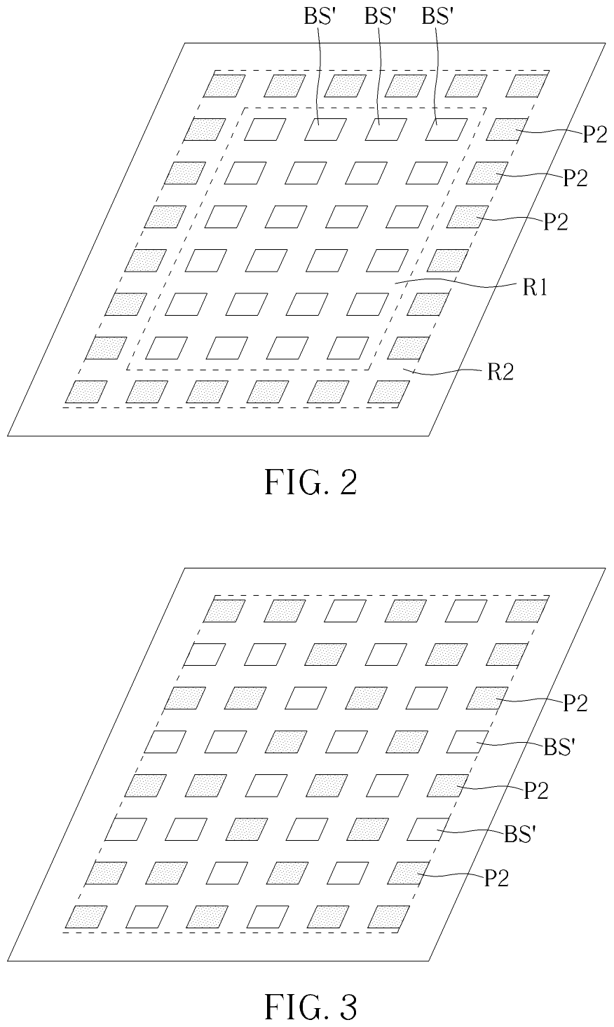

Please refer to FIG. 2 and FIG. 1. FIG. 2 is a schematic drawing illustrating an integrated circuit according to an embodiment of the present invention, which mainly shows the relative positions of the first region R1, the second region R2, a metal bump structure BS′, and the second connection pads P2, and the metal bump structure BS′ represents the metal bump structure BS except the second connection pads P2. As shown in FIG. 2 and FIG. 1, in some embodiments, the first region R1 may be surrounded by the second region R2, the second region R2 may be regarded as a peripheral region, and the second connection pads P2 located on the second region R2 may be electrically connected with outer circuits by wire bonding or other suitable approaches. Therefore, in some embodiments, the connection material 70 on the second connection pad P2 may include a wire bonding ball, and the connection material 70 may include an electrically conductive metal material, but not limited thereto. In addition, by forming the MIM capacitor CP on the metal bump structure BS, the space above the interconnection layer 30 maybe utilized for forming the relatively large MIM capacitor CP for meeting the needs of the related products. For example, the MIM capacitor CP may be applied in a radiofrequency device or other high frequency devices, such as being used as a decoupling capacitor and/or a filter capacitor in the radiofrequency device, but not limited thereto.

Please refer to FIG. 3 and FIG. 1. FIG. 3 is a schematic drawing illustrating an integrated circuit according to another embodiment of the present invention, which mainly shows the relative positions of the metal bump structure BS′ and the second connection pads P2, and the metal bump structure BS′ may include the metal bump structure BS except the second connection pads P2. As shown in FIG. 3 and FIG. 1, in some embodiments, the second connection pads P2 and the metal bump structure BS′ (i.e. the metal bump structure BS except the second connection pads P2, such as the first bump DB1, the second bump DB2, and/or the first connection pad P1) may be alternately arranged and disposed on the substrate 10, and the substrate 10 maybe regarded as a substrate including a plurality of first regions R1 and a plurality of second regions R2 arranged alternately, but not limited thereto. Under the design described above, the integrated circuit 101 may be bonded with other circuits and/or chips by a flip chip approach, and the connection material 70 may include a solder ball or other solder structures. In addition, in the flip chip packaging process, the connection material 70 maybe partly disposed above the passivation layer 68 and have a structure protruding upwards, but not limited thereto. It is worth noting that the above-mentioned design in FIG. 2 and FIG. 3 and the corresponding packaging approaches may be applied to other embodiments of the present invention also according to some design considerations.

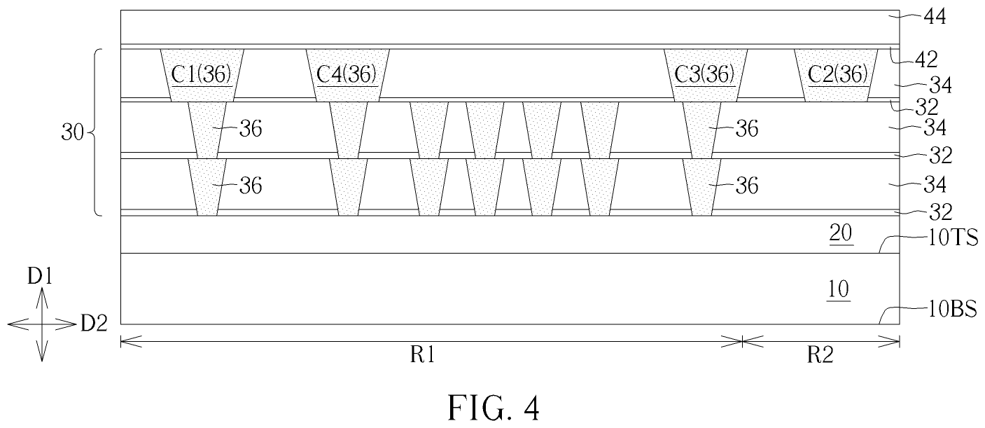

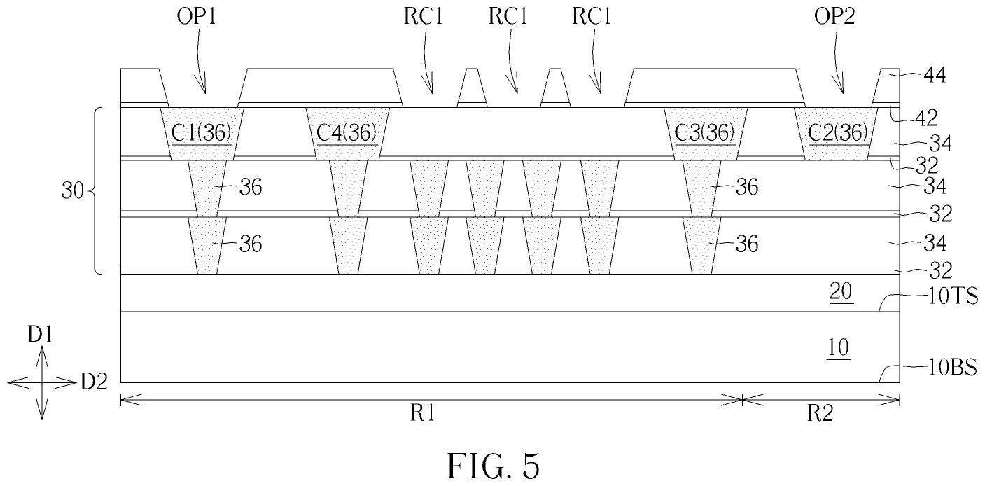

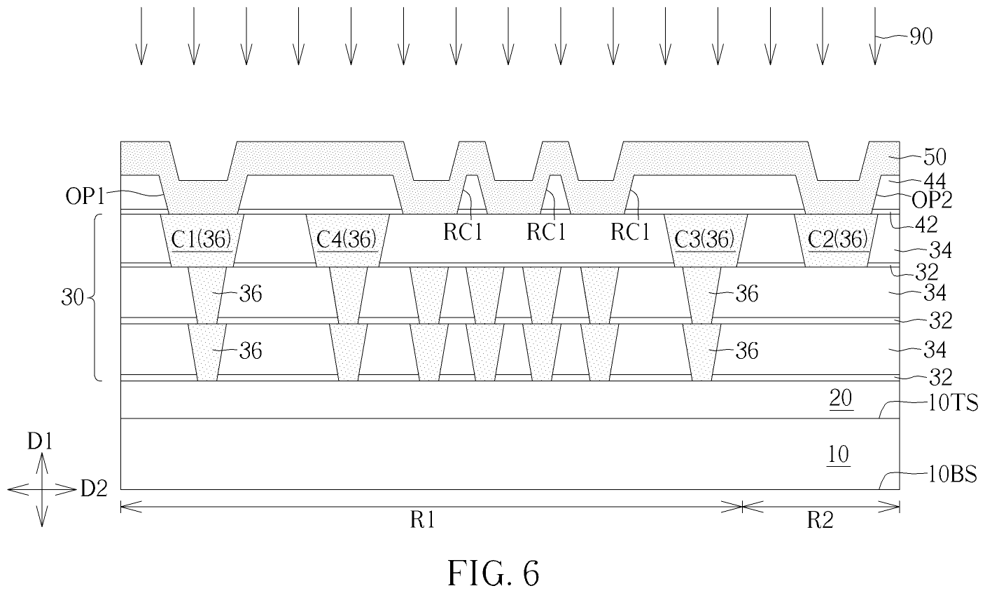

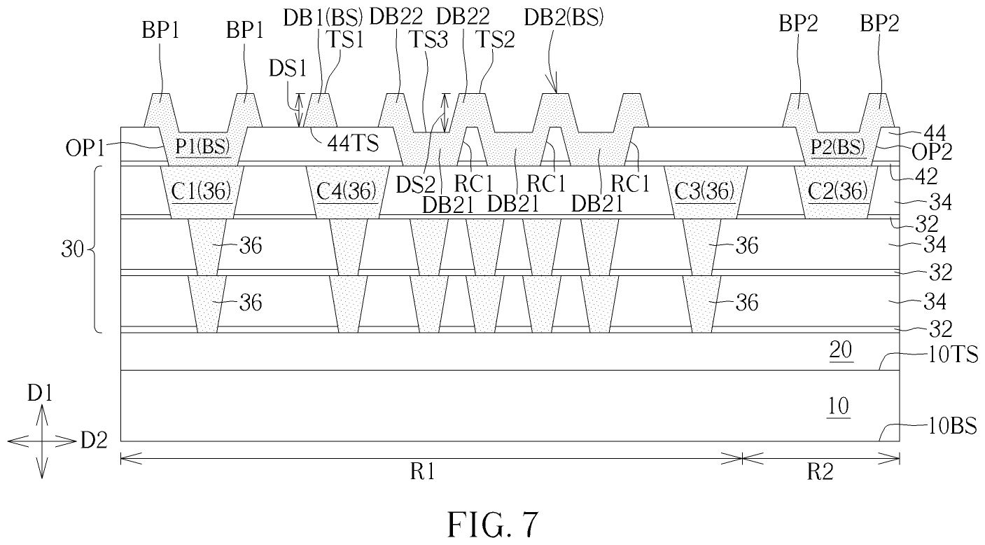

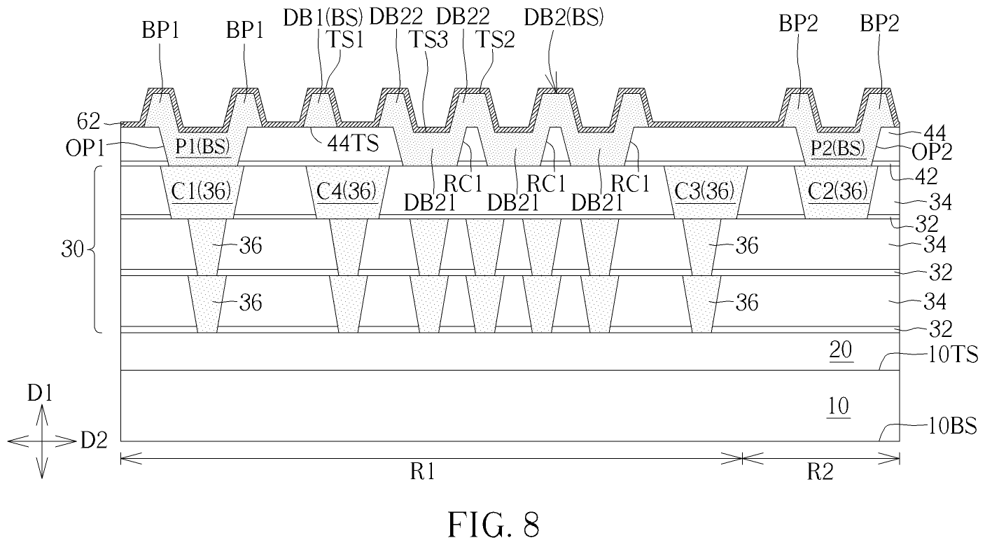

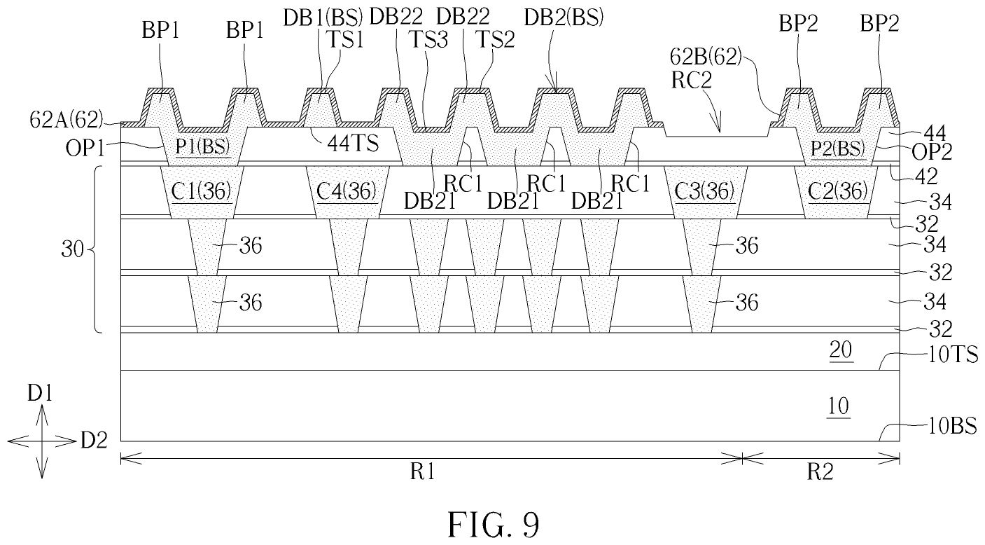

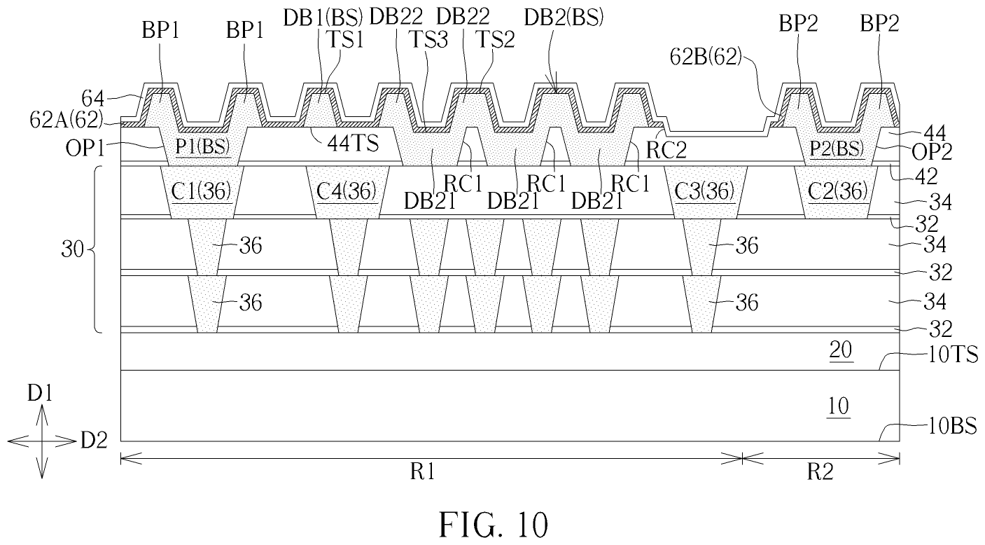

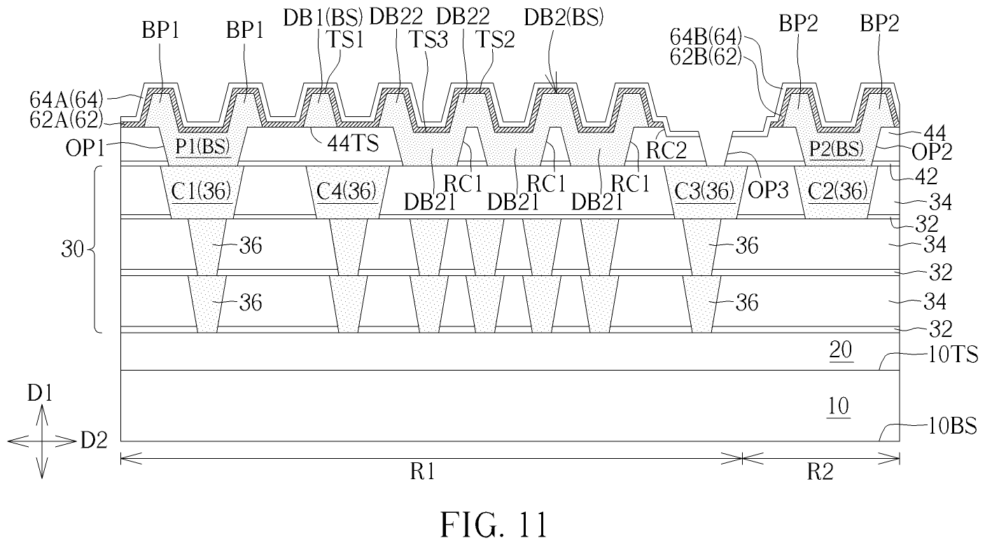

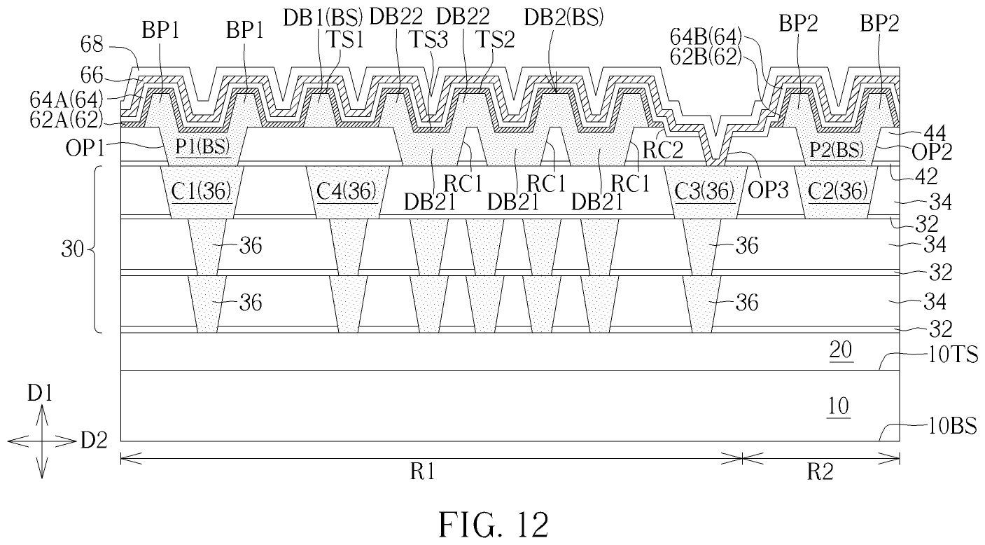

Please refer to FIG. 1 and FIGS. 4-12. FIGS. 4-12 are schematic drawings illustrating a manufacturing method of an integrated circuit according to the first embodiment of the present invention, wherein FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, and FIG. 1 maybe regarded as a schematic drawing in a step subsequent to FIG. 12, but not limited thereto. As shown in FIG. 1, the manufacturing method of the integrated circuit in this embodiment may include the following steps. The interconnection layer 30 is formed above the substrate 10. The interconnection layer 30 includes the interlayer dielectric layer 34 and the interconnection structure 36 disposed in the interlayer dielectric layer 34. The insulation layer 44 is formed on the interconnection layer 30, the metal bump structure BS is formed on the insulation layer 44, and the metal-insulator-metal (MIM) capacitor CP is formed conformally on the metal bump structure BS and the insulation layer 44.

Specifically, the manufacturing method of the integrated circuit in this embodiment may include but is not limited to the following steps. As shown in FIG. 4, after the steps of forming the device layer 20 and the interconnection layer 30 on the substrate 10, the etching stop layer 42 maybe formed, and the insulation layer 44 maybe formed on the etching stop layer 42. Subsequently, as shown in FIG. 5, the recess RC1, the opening OP1, and the opening OP2 described above may be formed. The recess RC1 may penetrate through the insulation layer 44 and the etching stop layer 42 and expose a part of the topmost interlayer dielectric layer 34 in the interconnection layer 30, the opening OP1 may penetrate through the insulation layer 44 and the etching stop layer 42 and expose a part of the top connection portion C1, and the opening OP2 may penetrate through the insulation layer 44 and the etching stop layer 42 and expose a part of the top connection portion C2. As shown in FIG. 6, a metal layer 50 is then formed, the metal layer 50 maybe partly formed above the insulation layer 44 and partly formed in the recess RC1, the opening OP1, and the opening OP2, and the recess RC1, the opening OP1, and the opening OP2 are formed before the step of forming the metal layer 50. The metal layer 50 may include aluminum or other suitable metallic materials, and the metal bump structure made of the metal layer 50 maybe regarded as an aluminum bump structure, but not limited thereto. Subsequently, as shown in FIG. 6 and FIG. 7, a patterning process 90 maybe performed to the metal layer 50, and the metal layer 50 maybe patterned to be the metal bump structure BS described above by the patterning process 90. For example, a portion of the metal layer 50 maybe patterned to be the first bump DB1, the second bump DB2, the first connection pad P1, and/or the second connection pad P2 described above by the patterning process 90. The first bump DB1 may be formed on the top surface 44TS of the insulation layer 44, the second bump DB2 may be formed partly in the recess RC1 and partly on the top surface 44TS of the insulation layer 44, the first connection pad P1 may be formed partly in the opening OP1 and partly on the top surface 44TS of the insulation layer 44, and the second connection pad P2 may be formed partly in the opening OP2 and partly on the top surface 44TS of the insulation layer 44. In addition, the patterning process 90 and other patterning processes used in the present invention may include photolithographic processes or other suitable patterning approaches.

In some embodiments, the depth of the opening OP1 and the depth of the recess RC1 in the vertical direction D1 (may be regarded as the total thickness of the etching stop layer 42 and the insulation layer 44 also) may be greater than the thickness of the metal layer 50, the top surface of the metal bump structure BS located in the opening OP1 and the recess RC1 (such as the top surface TS3 of the first portion DB21 described above) may be lower than the top surface 44TS of the insulation layer 44, and a relatively great surface step height may be formed accordingly, but not limited thereto. In other words, the surface step height of the metal bump structure BS may be adjusted by controlling the total thickness of the etching stop layer 42 and the insulation layer 44 and the thickness of the metal layer 50, and a distance DS2 between the top surface TS2 of the second portion DB22 of the second bump DB2 and the top surface TS3 of the first portion DB21 in the vertical direction D1 may be greater than a distance DS1 between the top surface TS1 of the first bump DB1 and the top surface 44TS of the insulation layer 44 in the vertical direction D1. In some embodiments, the shapes and the dimensions of the first bump DB1, the second portion DB22 of the second bump DB2, and the protruding portion BP1 of the first connection pad P1 may be similar to one another, and the spacing between the first bump DB1, the second portion DB22, and the protruding portion BP1 and/or the arrangement pitch of first bump DB1, the second portion DB22, and the protruding portion BP1 may range from 180 nanometers to several micrometers, but not limited thereto. In addition, the method of forming the metal bump structure BS in this invention may include but is not limited to the steps described above. In some embodiments, the metal bump structure BS illustrated in FIG. 1 and FIG. 7 maybe formed by other approaches according to some design considerations.

As shown in FIG. 8, after the step of forming the metal bump structure BS, an electrically conductive layer 62 maybe formed conformally on the metal bump structure BS and the insulation layer 44. As shown in FIG. 9, the electrically conductive layer 62 maybe patterned to be the bottom plate 62A and the electrically conductive pattern 62B. In some embodiments, in a patterning process performed to the electrically conductive layer 62, a part of the electrically conductive layer 62 and a part of the insulation layer 44 maybe removed for forming a recess RC2, a part of the electrically conductive layer 62 maybe patterned to be the bottom plate 62A, and another part of the electrically conductive layer 62 maybe patterned to be the electrically conductive pattern 62B. The recess RC2 may be located between the bottom plate 62A and the electrically conductive pattern 62B, and the recess RC2 does not penetrate through the whole insulation layer 44 in the vertical direction D1. Additionally, the bottom plate 62A may be formed conformally on the first bump DB1, the second bump DB2, and the first connection pad P1 of the metal bump structure BS, and the electrically conductive pattern 62B may be formed conformally on the second connection pad P2 of the metal bump structure BS. The bottom plate 62A may be electrically connected with the first connection pad P1, and the bottom plate 62A may be electrically connected with the top connection portion C1 of the interconnection structure 36 via the first connection pad P1. Subsequently, as shown in FIG. 10, a dielectric layer 64 is formed conformally on the bottom plate 62A, the electrically conductive pattern 62B, and the insulation layer 44. In some embodiments, the thickness of the dielectric layer 64 maybe controlled for avoiding negative influence on the capacitance of the capacitor subsequently formed. For example, when the material of the dielectric layer 64 is a high-k dielectric material, the thickness of the dielectric layer 64 may range from 5 angstroms to 80 angstroms, and the thickness of the dielectric layer 64 may range from 80 angstroms to 500 angstroms when the material of the dielectric layer 64 (such as silicon nitride) is not a high-k dielectric material, but not limited thereto. Subsequently, as shown in FIG. 10 and FIG. 11, a patterning process may be performed after the step of forming the dielectric layer 64, a part of the dielectric layer 64 maybe patterned to be the capacitor dielectric layer 64A, and another part of the dielectric layer 64 maybe patterned to be the dielectric pattern 64B. The capacitor dielectric layer 64A may be formed conformally on the bottom plate 62A, and the dielectric pattern 64B may be formed conformally on the electrically conductive pattern 62B. In some embodiments, the opening OP3 may be formed in the patterning process performed to the dielectric layer 64, and the opening OP3 may penetrate through the dielectric layer 64 located in the recess RC2, the insulation layer 44, and the etching stop layer 42 in the vertical direction D1 for exposing a part of the top connection portion C3.

Subsequently, as shown in FIG. 12, an electrically conductive layer 66 and the passivation layer 68 maybe formed. A part of the electrically conductive layer 66 maybe formed conformally on the capacitor dielectric layer 64A and the dielectric pattern 64B, another part of the electrically conductive layer 66 maybe formed conformally in the opening OP3, and the passivation layer 68 maybe formed conformally on the electrically conductive layer 66. As shown in FIG. 12 and FIG. 1, a patterning process may then be performed to the passivation layer 68 and the electrically conductive layer 66, a part of the electrically conductive layer 66 maybe patterned to be the top plate 66A, another part of the electrically conductive layer 66 maybe patterned to be the electrically conductive pattern 66B, and a part of the passivation layer 68 maybe patterned to be the first portion 68A and the second portion 68B separated from each other. Therefore, the top plate 66A may be formed conformally on the capacitor dielectric layer 64A, and the first portion 68A of the passivation layer 68 maybe formed on the top plate 66A and located corresponding to the top plate 66A in the vertical direction D1 completely, but not limited thereto. In some embodiments, a part of the passivation layer 68, a part of the electrically conductive layer 66, and a part of the insulation layer 44 maybe removed in the patterning process performed to the passivation layer 68 and the electrically conductive layer 66 for forming a recess RC3, and the recess RC3 does not penetrate through the whole insulation layer 44 in the vertical direction D1. In some embodiments, an opening OP4 may be formed penetrating through the second portion 68B of the passivation layer 68, the electrically conductive pattern 66B, the dielectric pattern 64B, and the electrically conductive pattern 62B in the vertical direction D1 and expose a part of the second connection pad P2, and at least a part of the connection material 70 maybe formed in the opening OP4, but not limited thereto.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

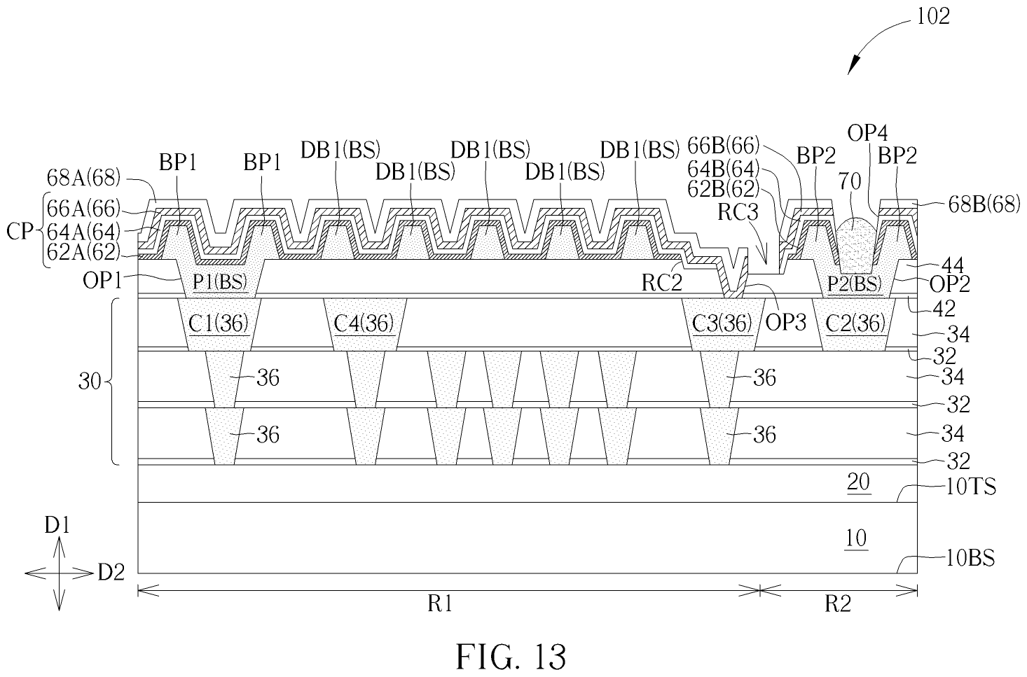

Please refer to FIG. 13. FIG. 13 is a cross-sectional schematic drawing illustrating an integrated circuit 102 according to a second embodiment of the present invention. As shown in FIG. 13, in the integrated circuit 102, except the connection pads (such as the first connection pad P1 and the second connection pad P2), the metal bump structure BS may not include a bump partly disposed in an opening penetrating through the insulation layer 44. In other words, the integrated circuit 102 may not include the second bump DB2 illustrated in FIG. 1 for avoiding electrical interference and influence caused by the too small distance between the bump in the metal bump structure BS being not directly connected with the interconnection structure 36 and the top connection portion of the interconnection structure 36.

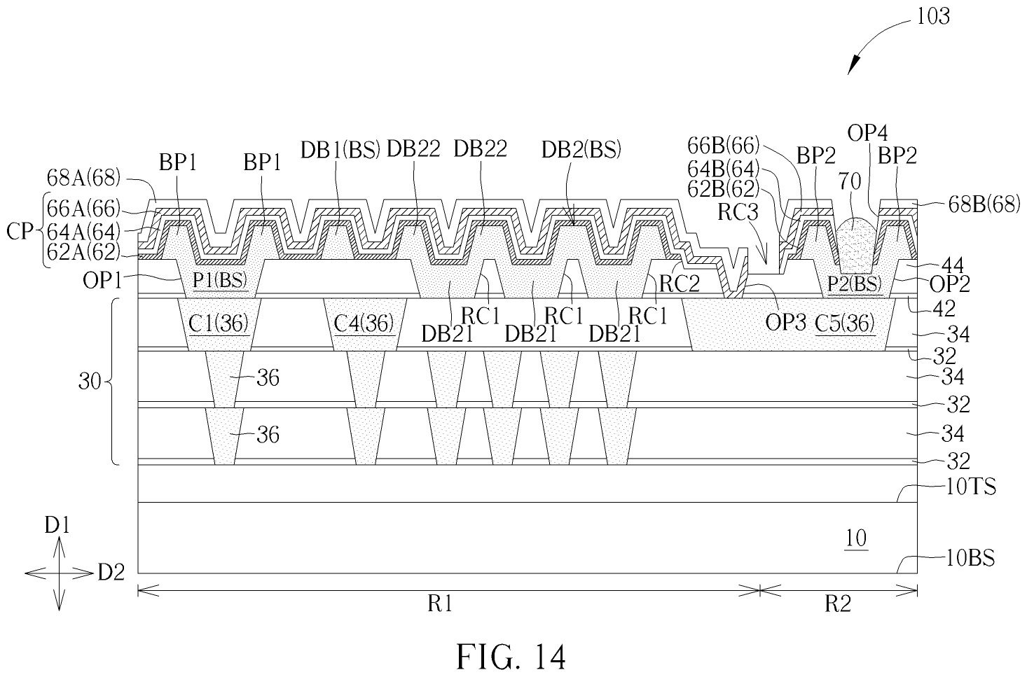

Please refer to FIG. 14. FIG. 14 is a cross-sectional schematic drawing illustrating an integrated circuit 103 according to a third embodiment of the present invention. As shown in FIG. 14, in the integrated circuit 103, the opening OP2 and the opening OP3 may be disposed on a top connection portion C5 of the interconnection structure 36. The top plate 66A of the MIM capacitor CP may be electrically connected with the top connection portion C5 by passing through the opening OP3, the second connection pad P2 may be electrically connected with the top connection portion C5 by passing through the opening OP2, and the top plate 66A of the MIM capacitor CP may be electrically connected with the second connection pad P2 and the connection material 70 via the top connection portion C5 accordingly. In the manufacturing method of the integrated circuit 102, the opening OP2 may expose a part of the top connection portion C5 of the interconnection structure 36 before the step of forming the metal bump structure BS, and the opening OP3 may expose another part of the top connection portion C5. In some embodiments, the connection material 70 maybe electrically connected to a device voltage terminal, and the bottom plate 62A of the MIM capacitor CP may be electrically connected to an electrical ground terminal via the first connection pad P1 and the interconnection structure 36. In the situation described above, the MIM capacitor CP may be used as a bypass capacitor and/or a decoupling capacitor for saving a peripheral passive area of a system in a package (SiP) or a printed circuit board (PCB).

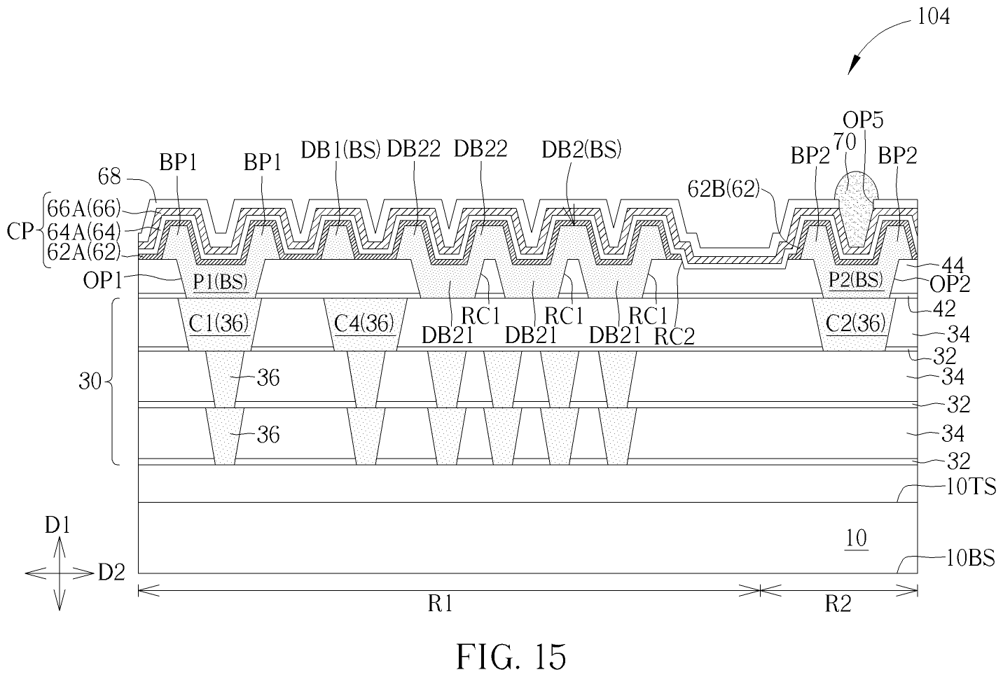

Please refer to FIG. 15. FIG. 15 is a cross-sectional schematic drawing illustrating an integrated circuit 104 according to a fourth embodiment of the present invention. As shown in FIG. 15, in the integrated circuit 104, the capacitor dielectric layer 64A and the top plate 66A of the MIM capacitor CP may be further disposed partly on the second connection pad P2 and the electrically conductive pattern 62B in the vertical direction D1, and an opening OP5 may penetrate through the passivation layer 68 and expose a part of the top plate 66A located above the second connection pad P2. Therefore, the connection material 70 may contact and be electrically connected with the top plate 66A by passing through the opening OP5, and the top plate 66A may be electrically connected with other outer circuits via the connection material 70. In some embodiments, the connection material 70 maybe disposed partly above the passivation layer 68 and include a structure protruding upwards, but not limited thereto. In addition, as shown in FIG. 15 and FIG. 3, in some embodiments, when the integrated circuit 104 is bonded with other circuits and/or chips by the flip chip approach, the capacitor dielectric layer 64A and the top plate 66A of the MIM capacitor CP may extend and be disposed above only one or some of the second connection pads P2, and the top connection portion C2 of the interconnection structure 36 may still be electrically connected to other outer circuits via the second connection pad P2 and the connection material 70 because other second connection pads P2 may not be covered by the capacitor dielectric layer 64A and the top plate 66A.

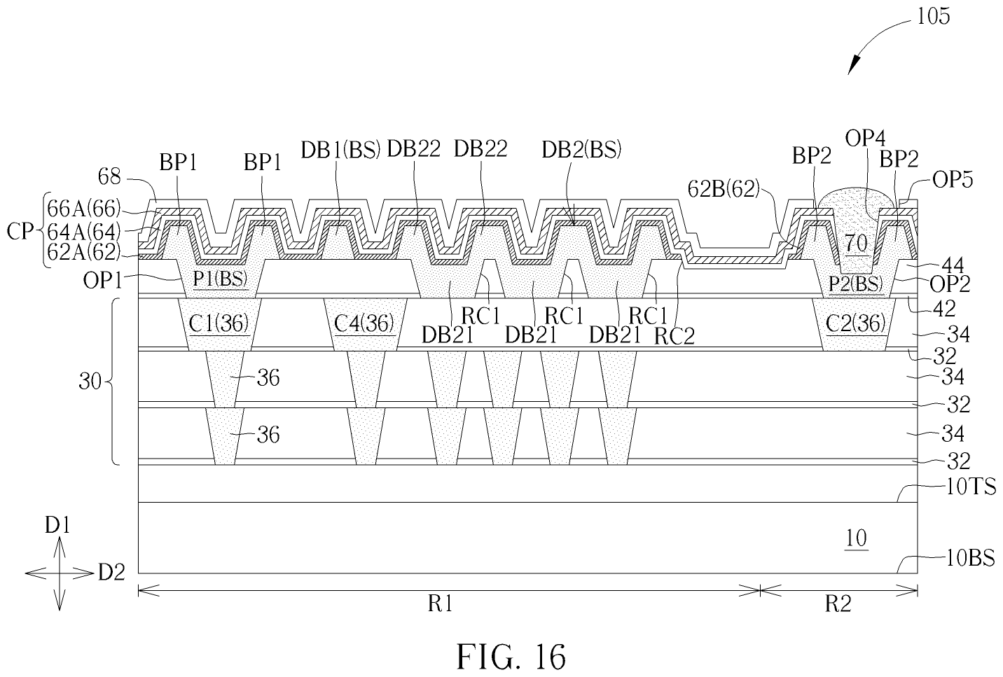

Please refer to FIG. 16. FIG. 16 is a cross-sectional schematic drawing illustrating an integrated circuit 105 according to a fifth embodiment of the present invention. As shown in FIG. 16, in the integrated circuit 105, the opening OP4 may penetrate through the electrically conductive pattern 62B, the capacitor dielectric layer 64A, and the top plate 66A located above the second connection pad P2 in the vertical direction D1 and expose a part of the second connection pad P2, and the opening OP5 may expose a part of the top plate 66A located above the second connection pad P2 in the vertical direction D1. In addition, the connection material 70 maybe disposed partly in the opening OP4 and disposed partly above the top plate 66A for contacting the top plate 66A and the second connection pad P2 and electrically connecting the top plate 66A and the second connection pad P2.

To summarize the above description, according to the integrated circuit and the manufacturing method thereof in the present invention, the MIM capacitor may be formed conformally on the metal bump structure and the insulation layer for increasing the surface area of the MIM capacitor by the surface step height of the metal bump structure, and the capacitance of the MIM capacitor may be relatively increased accordingly. In addition, the MIM capacitor in the present invention may be formed in the space above the interconnection layer, instead of being formed in the interconnection layer. The influence of the interconnection structure and the related limitations may be improved, and the relatively large capacitor structure may be formed to meet the needs of related products accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit, comprising:
a substrate;
an interconnection layer disposed above the substrate, wherein the interconnection layer comprises:
an interlayer dielectric layer; and
an interconnection structure disposed in the interlayer dielectric layer;
an insulation layer disposed on the interconnection layer;
a metal bump structure disposed on the insulation layer; and
a metal-insulator-metal (MIM) capacitor disposed conformally on the metal bump structure and the insulation layer.

2. The integrated circuit according to claim 1, wherein the metal bump structure comprises:
a first bump protruding upwards from a top surface of the insulation layer in a vertical direction, wherein the MIM capacitor comprises a bottom plate disposed conformally on the first bump and the insulation layer and directly connected with the first bump.

3. The integrated circuit according to claim 2, wherein a distance between a top surface of the first bump and the top surface of the insulation layer in the vertical direction ranges from 5000 angstroms to 30000 angstroms.

4. The integrated circuit according to claim 2, wherein the metal bump structure further comprises:
a first connection pad, wherein the bottom plate of the MIM capacitor is further disposed on and electrically connected with the first connection pad, a part of the first connection pad is disposed in a first opening penetrating through the insulation layer in the vertical direction for being electrically connected with a first top connection portion of the interconnection structure, and the bottom plate of the MIM capacitor is electrically connected with the first top connection portion of the interconnection structure via the first connection pad.

5. The integrated circuit according to claim 4, wherein the MIM capacitor further comprises:
a capacitor dielectric layer disposed conformally on the bottom plate; and
a top plate disposed conformally on the capacitor dielectric layer.

6. The integrated circuit according to claim 5, further comprising:
a passivation layer, wherein at least a portion of the passivation layer is disposed on the top plate and disposed corresponding to the top plate in the vertical direction completely.

7. The integrated circuit according to claim 5, wherein the metal bump structure further comprises:
a second connection pad separated from the first bump and the first connection pad, wherein a part of the second connection pad is disposed in a second opening penetrating through the insulation layer in the vertical direction.

8. The integrated circuit according to claim 7, wherein the MIM capacitor is electrically separated from the second connection pad, the second connection pad is electrically connected with a second top connection portion of the interconnection structure, and a part of the top plate is disposed in a third opening penetrating through the insulation layer in the vertical direction for being electrically connected with a third top connection portion of the interconnection structure.

9. The integrated circuit according to claim 7, wherein a part of the top plate is disposed in a third opening penetrating through the insulation layer in the vertical direction for being electrically connected with the second connection pad via a fourth top connection portion of the interconnection structure.

10. The integrated circuit according to claim 7, wherein the top plate is further disposed above the second connection pad.

11. The integrated circuit according to claim 1, wherein the metal bump structure comprises:
a second bump, wherein the second bump comprises:
a first portion disposed in a recess penetrating through the insulation layer in a vertical direction; and
a second portion disposed on the insulation layer and connected with the first portion, wherein a top surface of the second portion is higher than a top surface of the insulation layer in the vertical direction, and a top surface of the first portion is lower than the top surface of the insulation layer in the vertical direction.

12. A manufacturing method of an integrated circuit, comprising:
forming an interconnection layer above a substrate, wherein the interconnection layer comprises:
an interlayer dielectric layer; and
an interconnection structure disposed in the interlayer dielectric layer;
forming an insulation layer on the interconnection layer;
forming a metal bump structure on the insulation layer; and
forming a metal-insulator-metal (MIM) capacitor conformally on the metal bump structure and the insulation layer.

13. The manufacturing method of the integrated circuit according to claim 12, wherein a method of forming the metal bump structure comprises:
forming a metal layer on the insulation layer; and
performing a patterning process to the metal layer, wherein the metal layer is patterned to be the metal bump structure by the patterning process.

14. The manufacturing method of the integrated circuit according to claim 13, wherein the method of forming the metal bump structure further comprises:
forming a recess penetrating through the insulation layer in a vertical direction before the step of forming the metal layer, wherein the metal layer is partly formed in the recess, a portion of the metal layer is patterned to be a bump by the patterning process, and the bump comprises:
a first portion disposed in the recess; and
a second portion disposed on the insulation layer and connected with the first portion, wherein a top surface of the second portion is higher than a top surface of the insulation layer in the vertical direction, and a top surface of the first portion is lower than the top surface of the insulation layer in the vertical direction.

15. The manufacturing method of the integrated circuit according to claim 13, wherein the method of forming the metal bump structure further comprises:
forming a first opening penetrating through the insulation layer in a vertical direction and exposing a part of a first top connection portion of the interconnection structure before the step of forming the metal layer, wherein the metal layer is partly formed in the first opening, and a portion of the metal layer is patterned to be a first connection pad partly located in the first opening by the patterning process.

16. The manufacturing method of the integrated circuit according to claim 15, wherein the MIM capacitor comprises a bottom plate, the bottom plate is formed on and electrically connected with the first connection pad, and the bottom plate is electrically connected with the first top connection portion of the interconnection structure via the first connection pad.

17. The manufacturing method of the integrated circuit according to claim 13, wherein the method of forming the metal bump structure further comprises:
forming a second opening penetrating through the insulation layer in a vertical direction before the step of forming the metal layer, wherein the metal layer is partly formed in the second opening, and a portion of the metal layer is patterned to be a second connection pad partly located in the second opening by the patterning process.

18. The manufacturing method of the integrated circuit according to claim 17, further comprising:
forming a third opening penetrating through the insulation layer in the vertical direction after the patterning process, wherein the MIM capacitor comprises a top plate, and the top plate is partly formed in the third opening.

19. The manufacturing method of the integrated circuit according to claim 18, wherein the second opening exposes a part of a second top connection portion of the interconnection structure, the third opening exposes another part of the second top connection portion, and the top plate of the MIM capacitor is electrically connected with the second connection pad via the second top connection portion of the interconnection structure.

20. The manufacturing method of the integrated circuit according to claim 12, wherein the MIM capacitor comprises:
a bottom plate formed conformally on the metal bump structure;
a capacitor dielectric layer conformally formed on the bottom plate; and
a top plate formed conformally on the capacitor dielectric layer, wherein the manufacturing method of the integrated circuit further comprises:
forming a passivation layer conformally on the top plate, wherein at least a portion of the passivation layer is located corresponding to the top plate in a vertical direction completely.
